(19) United States
(12) Patent Application Publication
(10) Pub. No.: US 2024/0376598 A1
(43) Pub. Date: Nov. 14, 2024

(54) PROCESS GAS RAMP DURING SEMICONDUCTOR PROCESSING

(71) Applicant: Lam Research Corporation, Fremont, CA (US)

(72) Inventors: Jasmine LIN, San Jose, CA (US); Anand CHANDRASHEKAR, Fremont, CA (US); Gang LIU, Fremont, CA (US); Xing ZHANG, San Jose, CA (US); Kaihan Abidi ASHTIANI, Cupertino, CA (US)

(21) Appl. No.: 18/690,678

(22) PCT Filed: Sep. 6, 2022
(86) PCT No.: PCT/US2022/042655

§ 371 Date: Mar. 8, 2024

Related U.S. Application Data
(60) Provisional application No. 63/243,010, filed on Sep. 10, 2021.

(51) Int. Cl. C23C 16/455; C23C 16/04; C23C 16/52; H01L 21/285; H01L 21/768

(52) U.S. Cl. CPC C23C 16/45523; C23C 16/045; C23C 16/52; H01L 21/28562; H01L 21/76879

(57) ABSTRACT

Provided herein are systems and methods for semiconductor processing including feature fill processes. The methods comprise providing a substrate having a feature to be filled with a metal in a chamber, and flowing a metal precursor and a reducing agent into the chamber to deposit metal in the feature in a chemical vapor deposition (CVD) operation, wherein the CVD operation comprises a ramp down stage in which the flow rate of the metal precursor into the chamber is ramped down from a first flow rate to a second flow rate. or a ramp up stage in which the flow rate of the metal precursor into the chamber is ramped up from the first flow rate to the second flow rate.

### INCORPORATION BY REFERENCE

A PCT Request Form is filed concurrently with this specification as part of the present application. Each application that the present application claims benefit of priority to as identified in the concurrently filed PCT Request Form is incorporated by reference herein in their entireties and for all purposes.

### BACKGROUND

Feature fill processes may be used to fill features on semiconductor substrates with metal or dielectric material. Chemical vapor deposition (CVD) processes can involve reacting two processes gases to deposit solid film in a feature. Advanced fill processes may be used to fill device features that have aggressive geometries. For example, a deposition-inhibition-deposition (DID) process may involve a first deposition followed by an inhibition process to inhibit deposition at the feature opening and a subsequent deposition to fill the feature.

The background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

Provided herein are systems and methods for semiconductor processing including feature fill processes. The methods involve ramping of a process gas flow rate during a process operation.

One aspect of the disclosure relates to a method of filling a feature with metal. The method includes providing a substrate having a feature to be filled with a metal in a chamber and flowing a metal precursor and a reducing agent into the chamber to deposit metal in the feature in a chemical vapor deposition (CVD) operation. The CVD operation includes a ramp down stage in which the flow rate of the metal precursor into the chamber is ramped down from a first flow rate to a second flow rate.

In some embodiments, the CVD operation includes a second stage, after the ramp down stage, in which the metal precursor flow rate is constant.

In some embodiments, the CVD operation includes a second stage, prior to the ramp down stage, in which the metal precursor flow rate is constant.

In some embodiments, the reducing agent flow rate is constant during the ramp down stage.

In some embodiments, the reducing agent flow rate is ramped during the ramp down stage.

In some embodiments, the method further includes, prior to the CVD operation, performing an inhibition treatment to inhibit metal deposition.

In some embodiments, metal deposition is inhibited preferentially near the feature opening.

In some embodiments, the feature includes a constriction and wherein a stage prior to the ramp down stage is used to fill a portion of the feature below the constriction.

In some embodiments, the ramp down stage is used to fill the constricted portion of the feature.

In some embodiments, the feature is a first feature having a first size and the substrate has a second feature having a second size, the second size being larger than the first size, and wherein the ramp down stage is used to complete fill of the first feature.

In some embodiments, the method further includes, after the first feature is completely filled, ramping up flow of the metal precursor from the second flow rate to a third flow rate.

Another aspect of the disclosure relates to a method of filling a feature with metal. The method includes a feature to be filled with a metal in a chamber and flowing a metal precursor and a reducing agent into the chamber to deposit metal in the feature in a chemical vapor deposition (CVD) operation. The CVD operation includes a ramp up stage in which the flow rate of the metal precursor into the chamber is ramped up from a first flow rate to a second flow rate.

In some embodiments, the substrate has a second feature, smaller than the feature any further includes filling the second feature. The ramp up stage may be performed after the second feature is completely filled and before the feature is completely filled.

In some embodiments, the CVD operation includes a second stage, after the ramp up stage, in which the metal precursor flow rate is constant.

In some embodiments, the CVD operation includes a second stage, prior to the ramp up stage, in which the metal precursor flow rate is constant.

In some embodiments, the reducing agent flow rate is constant during the ramp up stage.

In some embodiments, the reducing agent flow rate is ramped during the ramp up stage.

In some embodiments, the method further includes, prior to the CVD operation, performing an inhibition treatment to inhibit metal deposition.

Also described are apparatuses to implement the methods described herein.

These and other aspects of the disclosure are discussed further below with reference to the drawings.

### BRIEF DESCRIPTION OF DRAWINGS

FIG. 1A shows an example of a gas manifold that may be used in implementations described herein.

FIG. 1B illustrates examples of ramping of reactant gases over a stage.

FIGS. 2A-2H show examples of features that may be filled with metal according to various implementations.

FIGS. 3A and 3B illustrate examples of multi-stage deposition processes.

FIG. 4 is a flow diagram illustrating operations in a method of filling a feature.

FIG. 5 shows examples of a feature during various operations of FIG. 4.

FIG. 6 shows an example of ramping a flow during an atomic layer deposition (ALD) process.

FIG. 7 shows an example of an apparatus that may be used to implement the methods described herein.

FIG. 8 shows an example of a process station that may be used to implement the methods described herein.

### DETAILED DESCRIPTION

Provided herein are systems and methods for semiconductor processing including feature fill processes. The methods involve ramping of a process gas flow rate during a process operation. Examples of processes include chemical vapor deposition (CVD) processes, treatment processes, and etch processes.

In a specific example, filling a feature with metal can involve flowing a metal precursor and a reducing agent into a process chamber for a CVD reaction. The metal precursor flow rate is ramped down during at least a portion of the deposition. In some embodiments, ramping the metal precursor flow rate results in a low stress film and good fill characteristics. In another example, a reactant flow rate is ramped down as the deposition process begins to deposit film near the top of the feature to reduce the amount of film deposited as an overburden layer. These and other embodiments are discussed further below.

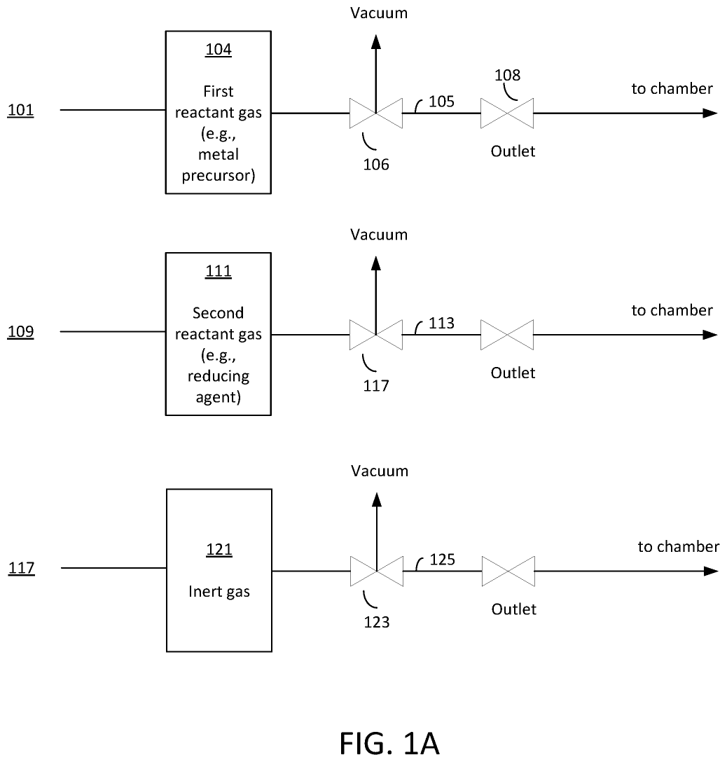

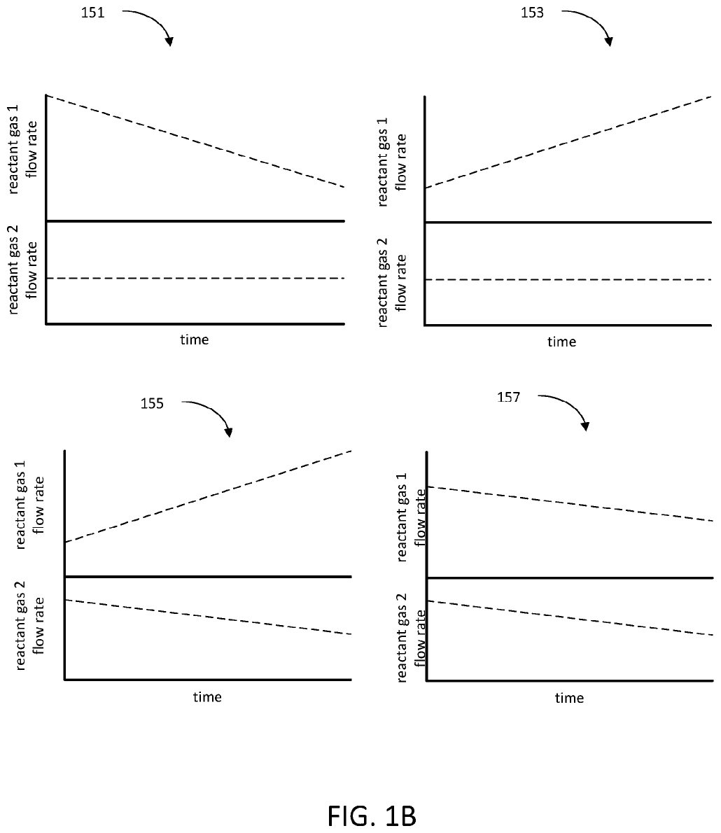

An apparatus used to perform the methods described herein may include a gas manifold system as shown in FIG. 1A. Manifold 104 has input 101 from a source of a first reactant gas (e.g., a metal-containing precursor gas). Manifold 111 has an input 109 from of source of a second reactant gas (e.g., hydrogen (H₂) or other reducing gas). There may or may not be an input from a carrier gas to manifold 104 and/or manifold 111. Manifold 121 has an input 117 from a source of inert gas. The manifolds 104, 111 and 121 provide process and/or carrier or purge gas to the deposition chamber through valved distribution lines 105, 113, and 125 respectively. The various valves may be opened or closed to provide a line charge, i.e., to pressurize the distribution lines. For example, to pressurize distribution line 105, valve 106 is closed to vacuum and valve 108 is closed. After a suitable increment of time, valve 108 is opened and the gas is delivered to the chamber. Similar processes can be used to deliver gases from manifolds 111 and 121. FIG. 1A also shows vacuum pumps in which valves 106, 117, and 123, respectively, can be opened to purge the system.

The supply of gas through the various distribution lines is controlled by a controller, such as a mass flow controller (MFC) which is controlled by a microprocessor, a digital signal processor or the like, that is programmed with the flow rates, duration of the flow, and the sequencing of the processes.

Valve and MFC commands are delivered to embedded digital input-output controllers (IOC) in discrete packets of information containing instructions for all time-critical commands for all or a part of a deposition sequence. The ALTUS systems of Lam Research provide at least one IOC sequence. The IOCs can be physically located at various points in the apparatus; e.g., within the process module or on a stand-alone power rack standing some distance away from the process module. There may be multiple IOCs in each module (e.g., 3 per module). With respect to the actual instructions included in a sequence, all commands for controlling valves and setting flow for MFCs (for all process and inert gases) may be included in a single IOC sequence. This assures that the timing of all the devices is tightly controlled from an absolute standpoint and also relative to each other. There may be multiple IOC sequences running at any given time.

A flow rate can be ramped up or down. According to various embodiments, ramp step duration may be as small as 300 microseconds or arbitrarily large. A particular process, such as a CVD deposition or an inhibition treatment, may have one or more stages. During each stage, the flow rate of each gas is a constant rate increase, a constant rate decrease, or constant.

According to various embodiments, each stage may be at least 3 seconds and arbitrarily long in duration.

FIG. 1B shows examples of ramping of reactant gases over a stage. The stage may be the only stage of a single stage process or one stage of a multi-stage process. At 151, a first reactant gas is shown ramping down while a second reactant gas has a constant flow rate. Similarly, at 153, a first reactant gas is ramped up while a second reactant gas has a constant flow rate. In some embodiments, both reactant gases may ramp during a stage as shown at 155 and 157. According to various embodiments, the directions of ramp may be the same (as at 157) or different (as at 155). Further, the rate of ramping may be the same or different.

According to various embodiments, an inert gas (e.g., a dilution gas) may be independently ramped or held constant during a stage. This may be done in addition or instead of ramping one or more reactant gases as show in FIG. 1B.

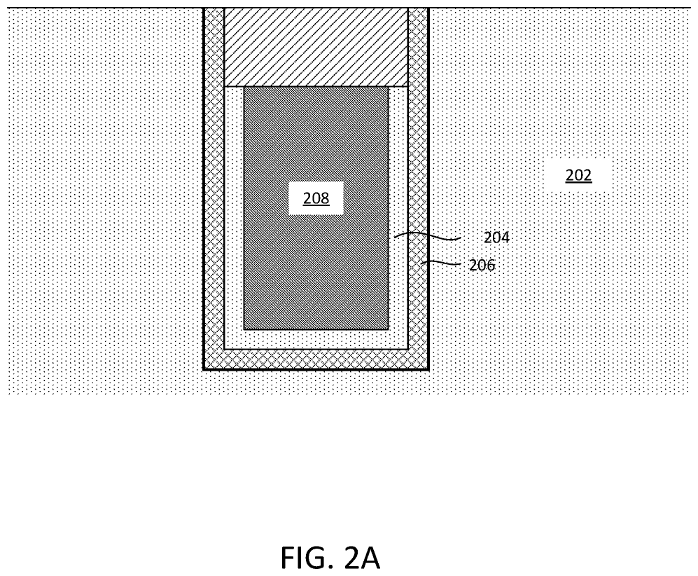

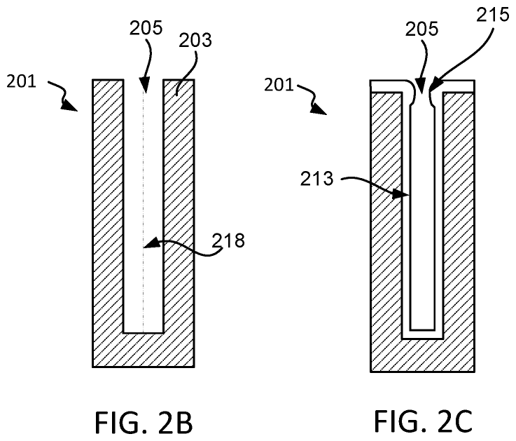

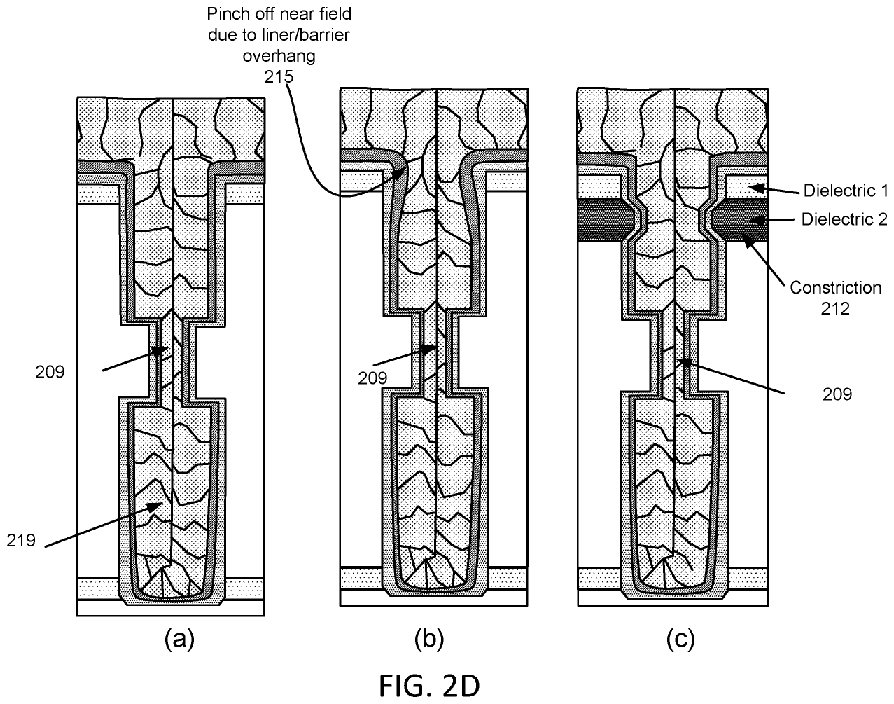

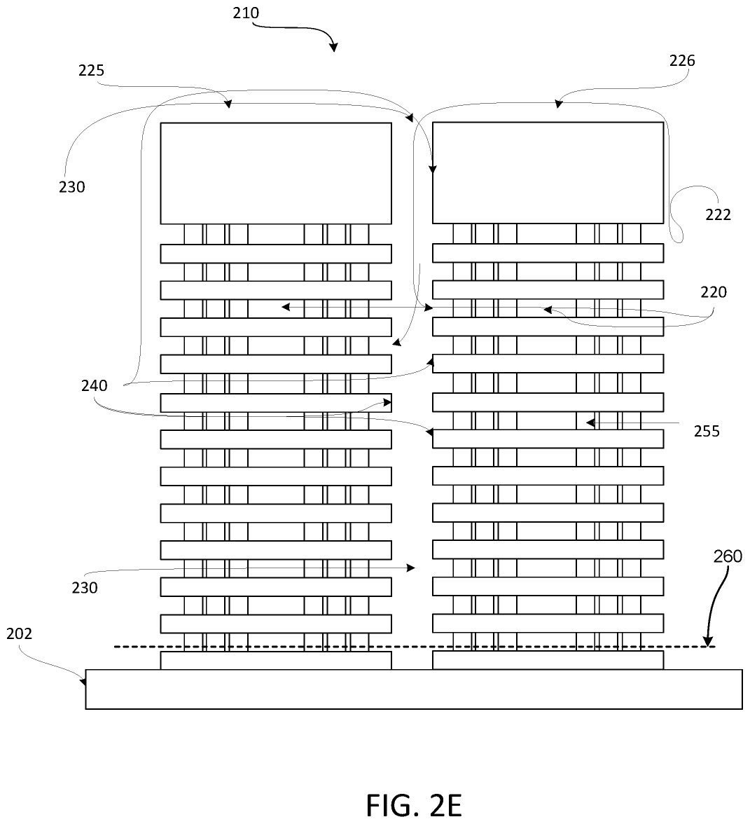

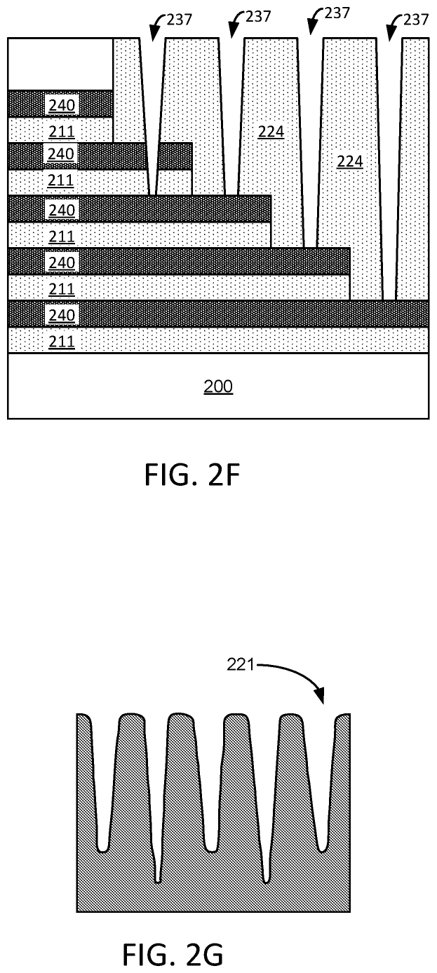

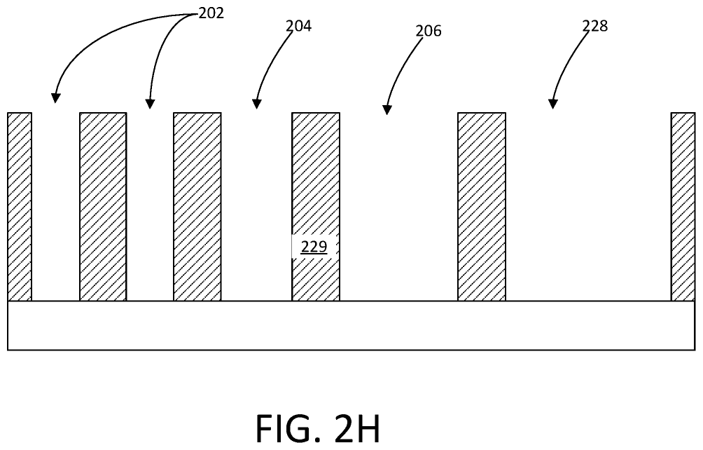

In some embodiments, the methods to fill a feature with a material are provided. For example, the methods may be used to fill a feature with a metal. Examples of features that may be filled with metal are provided in the description below with reference to FIGS. 2A-2H.

The methods described herein are performed on a substrate that may be housed in a chamber. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods are not limit to semiconductor substrates and may be performed to fill any feature with a metal-containing or other material.

Substrates may have features such as via or contact holes, which may be characterized by one or more of narrow and/or re-entrant openings, constrictions within the feature, and high aspect ratios. A feature may be formed in one or more of the above described layers. For example, the feature may be formed at least partially in a dielectric layer. In some embodiments, a feature may have an aspect ratio of at least about 2:1, at least about 4:1, at least about 6:1, at least about 10:1, at least about 25:1, or higher. One example of a feature is a hole or via in a semiconductor substrate or a layer on the substrate.

FIG. 2A depicts a schematic example of a DRAM architecture including a metal buried wordline (bWL) 208 in a silicon substrate 202. The metal bWL is formed in a trench etched in the silicon substrate 202. Lining the trench is a conformal barrier layer 206 and an insulating layer 204 that is disposed between the conformal barrier layer 206 and the silicon substrate 202. In the example of FIG. 2A, the insulating layer 204 may be a gate oxide layer, formed from a high-k dielectric material such as a silicon oxide or silicon nitride material. In some embodiments disclosed herein the conformal barrier layer is TIN or a tungsten-containing layer. In some embodiments, one or both of layers 204 and 206 is not present.

The bWL structure shown in FIG. 2A is one example of an architecture that includes a conductive metal fill layer. During fabrication of the bWL, a conductive metal film is deposited into a feature that may be defined by an etched recess in the silicon substrate 202 that is conformally lined with layers 206 and 204, if present.

FIGS. 2B-2H are additional schematic examples of various structures into which a metal fill layer may be deposited in accordance with disclosed embodiments. FIG. 2B shows an example of a cross-sectional depiction of a vertical feature 201 to be filled with metal. The feature can include a feature hole 205 in a substrate. The hole 205 or other feature may have a dimension near the opening, e.g., an opening diameter or line width of between about 10 nm to 500 nm, for example between about 25 nm and about 300 nm. The feature hole 205 can be referred to as an unfilled feature or simply a feature. The feature 201, and any feature, may be characterized in part by an axis 218 that extends through the length of the feature, with vertically-oriented features having vertical axes and horizontally-oriented features having horizontal axes.

In some embodiments, features are wordline features in a 3D NAND structure. For example, a substrate may include a wordline structure having an arbitrary number of wordlines (e.g., 50 to 150) with vertical channels at least 200 Å deep. Another example is a trench in a substrate or layer. Features may be of any depth. In various embodiments, the feature may have an under-layer, such as a barrier layer or adhesion layer. Non-limiting examples of under-layers include dielectric layers and conducting layers, e.g., silicon oxides, silicon nitrides, silicon carbides, metal oxides, metal nitrides, metal carbides, and metal layers.

FIG. 2C shows an example of a feature 201 that has a re-entrant profile. A re-entrant profile is a profile that narrows from a bottom, closed end, or interior of the feature to the feature opening. According to various implementations, the profile may narrow gradually and/or include an overhang at the feature opening. FIG. 2C shows an example of the latter, with an under-layer 213 lining the sidewall or interior surfaces of the feature hole 105. The under-layer 213 can be for example, a diffusion barrier layer, an adhesion layer, a nucleation layer, a combination of thereof, or any other applicable material. Non-limiting examples of under-layers can include dielectric layers and conducting layers, e.g., silicon oxides, silicon nitrides, silicon carbides, metal oxides, metal nitrides, metal carbides, and metal layers. In particular implementations an under-layer can be one or more of titanium, titanium nitride, tungsten nitride, titanium aluminide, tungsten, and molybdenum. In some embodiments, the under-layer is different from or does not contain the metal of the metal conductive layer. In some embodiments, the under-layer is tungsten-free. In some embodiments, the under-layer is molybdenum-free. The under-layer 213 forms an overhang 215 such that the under-layer 213 is thicker near the opening of the feature 201 than inside the feature 201.

In some implementations, features having one or more constrictions within the feature may be filled. FIG. 2D shows examples of views of various filled features having constrictions. Each of the examples (a), (b) and (c) in FIG. 2D includes a constriction 209 at a midpoint within the feature. The constriction 209 can be, for example, between about 15 nm-20 nm wide. Constrictions can cause pinch off during deposition of tungsten, molybdenum, or other conductive material in the feature using conventional techniques, with deposited metal blocking further deposition past the constriction before that portion of the feature is filled, resulting in voids in the feature. Example (b) further includes a liner/barrier overhang 215 at the feature opening. Such an overhang could also be a potential pinch-off point. Example (c) includes a constriction 212 further away from the field region than the overhang 215 in example (b).

In some embodiments, deposition into a feature including constriction may start with a high flow rate of a metal-containing precursor for a short period of time to ensure the metal-containing precursor can reach the very bottom of the feature (beyond the constriction) and fill it. An example of high flow rate is 1200 sccm. Then, the metal-containing precursor flow is ramped down to a lower flow rate, e.g., 1200 sccm to 200 sccm, when filling the narrow constriction. Once the narrow part of the feature is filled, the metal-containing precursor may be held constant at the low flow rate to enable lower stress film near the top of the feature without compromising fill performance. In some embodiments, such a ramped deposition may be the second deposition of a deposition-inhibition-deposition (DID) sequence.Horizontal features, such as in 3-D memory structures, can also be filled. For example, a horizontal feature may be a word line features in a 3D NAND (also referred to as vertical NAND or VNAND) structure. In some implementations, the constrictions can be due to the presence of pillars in a 3D NAND or other structure. FIG. 2E presents a cross-sectional side-view of a 3-D NAND structure 210 (formed on a silicon substrate 202) having VNAND stacks (left 225 and right 226), central vertical structure 230, and a plurality of stacked horizontal features 220 with openings 222 on opposite sidewalls 240 of central vertical structure 230. Note that FIG. 2F displays two “stacks” of the exhibited 3-D NAND structure 210, which together form the “trench-like” central vertical structure 230, however, in certain embodiments, there may be more than two “stacks” arranged in sequence and running spatially parallel to one another, the gap between each adjacent pair of “stacks” forming a central vertical structure 230, like that explicitly illustrated in FIG. 2F. In this embodiment, the horizontal features 120 are 3-D memory wordline features that are fluidically accessible from the central vertical structure 230 through the openings 222. Although not explicitly indicated in the figure, the horizontal features 220 present in both the 3-D NAND stacks 225 and 226 shown in FIG. 2E (i.e., the left 3-D NAND stack 225 and the right 3-D NAND stack 226) are also accessible from the other sides of the stacks (far left and far right, respectively) through similar vertical structures formed by additional 3-D NAND stacks (to the far left and far right, but not shown). In other words, each 3-D NAND stack 225, 226 contains a stack of wordline features that are fluidically accessible from both sides of the 3-D NAND stack through a central vertical structure 1230. In the particular example schematically illustrated in FIG. 2F, each 3-D NAND stack contains 6 pairs of stacked wordlines, however, in other embodiments, a 3-D NAND memory layout may contain any number of vertically stacked pairs of wordlines.

In some embodiments, metal precursor flow rate may be increased during fill of the innermost and bottommost areas of complex 3-D structures to be filled. The methods may also be used to fill interconnect features to 3D wordlines. FIG. 2F shows a partially fabricated 3D NAND device having such a feature. Alternating oxide layers 211 and metal wordlines 240 on a substrate 200 are shown in a staircase structure. Although five metal wordlines 240 are depicted for ease of illustration, according to various implementations, a structure may include any number of wordlines, such 48 wordlines, 256 wordlines, 512 wordlines, or 1024 wordlines. In some implementations, the feature to be filled is at least 10 microns deep, or at least 20 microns deep.

An oxide layer 224 is deposited over the staircase structure, with features 237 etched in the oxide layer 224. These features 237 may be filled with metal using the methods described herein to provide interconnects to the wordlines 240.

The methods may also be used to fill multiple adjacent features, such as DRAM bWL trenches. Fill processes for DRAM bWL trenches can distort the trenches such that the final trench width and resistance are significantly non-uniform. This phenomenon is referred to as line bending. FIG. 2G shows an unfilled 221 narrow asymmetric trench structure DRAM bWL that exhibit line bending after fill. As shown, multiple features are depicted on a substrate. These features are spaced apart, and in some embodiments, adjacent features have a pitch between about 20 nm and about 60 nm or between about 20 nm and 40 nm. The pitch is defined as the distance between the middle axis of one feature to the middle axis of an adjacent feature. The unfilled features may be generally V-shaped as shown in the example of FIG. 2G, having sloped sidewalls where the width of the feature narrows from the top of the feature to the bottom of the feature. The features widen from the feature bottom to the feature top. Sequences of depositions that use inhibition may be used to mitigate line bending. These include inhibiting the full depth of the features.

In some embodiments, the methods are used to fill structures having features of different sizes. FIG. 2H shows an example of such a structure, which includes small features 202 and larger features 204, 206, and 228 etched in dielectric layer 229. In one example, the structure in FIG. 2H can be filled starting from high tungsten-containing precursor (e.g., tungsten hexafluoride (WFs)) flow and then ramped down to low flow when features 202 are close to being filled. At low flow WFs, the tungsten grain size is smaller and results in a smoother interface at the seam with less void space. Once features 202 are filled, WF6 flow is then ramped up to fill feature 204 and ramped down before feature 204 is fully filled. A low flow of WF6 is used to complete fill of feature 204. As similar ramp up and then ramp down protocol can be used to fill features 206 and 228.

In some embodiments, the methods involve deposition of a first metal layer in a feature. The first metal layer may be a nucleation layer, a bulk layer, or a bulk layer deposited on a nucleation layer. It may be deposited by an ALD process to conformally line the feature. The first metal layer may be exposed to an inhibition treatment. In some embodiments, the inhibition treatment is preferentially applied near the top of the feature, such that subsequent deposition in the bottom of the feature is not inhibited or inhibited to a lesser extent than near the top. This results in bottom-up fill.

Examples of feature fill for horizontally-oriented and vertically-oriented features are described below. It should be noted that in at least most cases, the examples are applicable to both horizontally-oriented (parallel to the plane of the substrate) or vertically-oriented (orthogonal to the plane of the substrate) features.

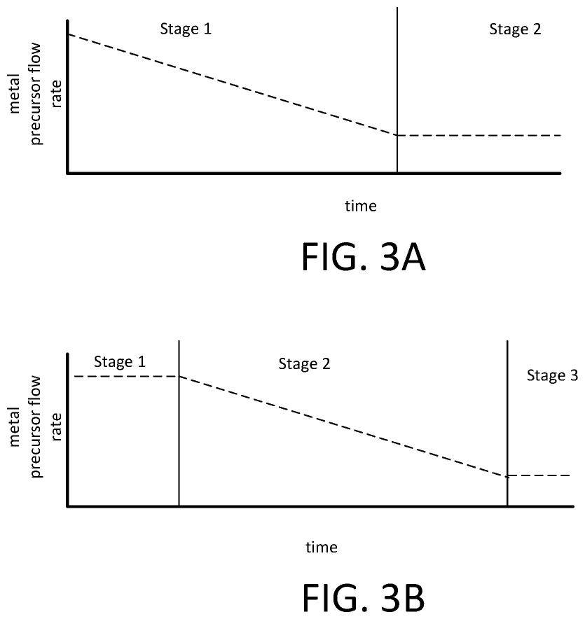

In some embodiments, filling a feature with a metal may involve starting deposition at a high metal precursor flow rate and ramping down during deposition. In some embodiments, a single stage CVD deposition may be used such as at 151 in FIG. 1B, with reactant 1 being a metal precursor such as tungsten hexafluoride (WF6) and reactant 2 being hydrogen gas (H₂). In other embodiments, a uniform flow rate may be used prior to or after ramping. FIGS. 3A and 3B show examples of two-stage and three-stage processes, respectively. In FIG. 3A, the metal precursor starts at a high flow rate and is ramped down in Stage 1. In Stage 2, it is at a constant, lower flow rate. In the example, of FIG. 3A, the beginning flow rate of Stage 2 is the ending flow rate of Stage 1. However, in other embodiments, these values may be different. In FIG. 3B, Stage 1 has a constant high flow rate for the metal precursor. Stage 2 ramps down, and Stage 3 is at constant lower flow rate. Stage 3 may be omitted in some embodiments.

The examples of FIGS. 3A and 3B, and other single or multi-stage sequences in which the metal precursor is ramped down during one stage may be used to fill features that have good fill but with lower stress. High flow rate at the beginning of a fill process can facilitate good fill characteristics, while ramping down the flow rate can result in a lower stress film. For features that have large openings, very high flow rates can be used to increase deposition rate and throughput at the beginning of deposition. As the feature closes, the metal precursor flow rate can be ramped down to ensure a smoother surface for seamless fill.

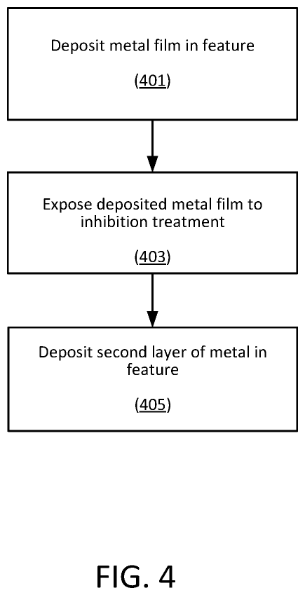

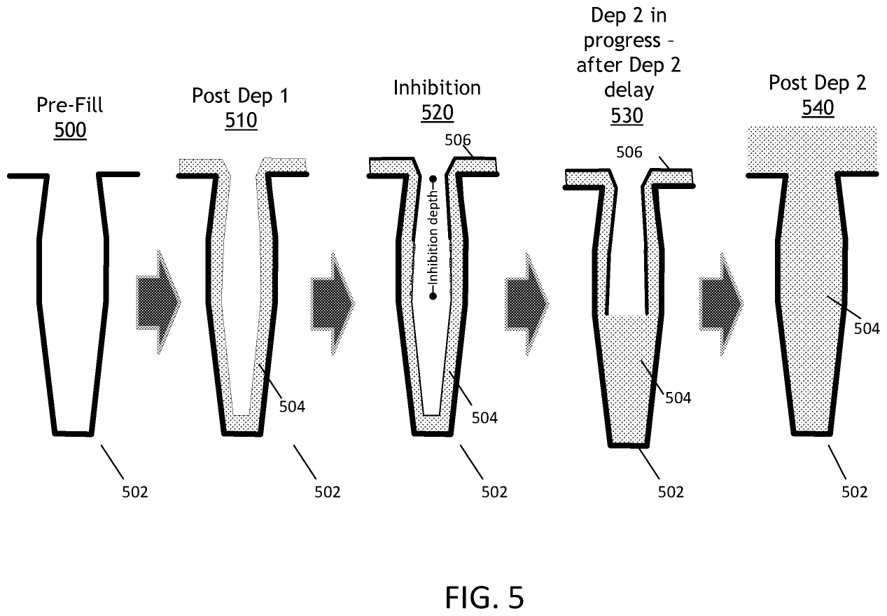

FIGS. 4 and 5 show an example of a deposition process including operations that implement a ramp stage. In FIG. 5, at 500, a feature 502 is shown at a pre-fill stage. The feature 502 may be formed in one or more layers on a semiconductor substrate and may optionally have one or more layers that line the sidewalls and/or bottom of the feature. Turning to FIG. 4, a metal film is deposited in the feature in an operation 401. This operation may be referred to as Dep1. In many embodiments, operation 401 is a generally conformal deposition that lines the exposed surfaces of the structures. For example, in a 3D NAND structure such as that shown in FIG. 2E, the metal film lines the wordline features 220. According to various embodiments, the metal film is deposited using an atomic layer deposition (ALD) process to achieve good conformality. Chemical vapor deposition (CVD) processes may be used in alternate embodiments. Still further, the process may also be carried out with any appropriate metal deposition including physical vapor deposition (PVD) or plating processes. In some embodiments, after operation 401, the features are not closed off, but sufficiently open to allow further reactant gases to enter the features in a subsequent deposition.

In an ALD process, the feature is exposed to alternating pulses of reactant gases. In the example of tungsten deposition, a tungsten-containing precursor such as tungsten hexafluoride (WF₆), tungsten hexachloride (WCle), tungsten pentachloride (WCl₅), tungsten hexacarbonyl (W(CO)6), or a tungsten-containing organometallic compound may be used. In some embodiments, pulses of the tungsten-containing precursor are pulsed with a reducing agent such as hydrogen (H₂), diborane (B₂H₆), silane (SiH₄), or germane (GeH₄). In a CVD method, the wafer is exposed to the reactant gases simultaneously. Deposition chemistries for other films are provided below. In FIG. 5, at 510, the feature 502 is shown after Dep1 to form a layer of the material 504 to be filled in the feature 502.

Next, in an operation 403 in FIG. 4, the deposited metal film is exposed to an inhibition treatment. This may be a conformal or non-conformal treatment. A non-conformal treatment in this context refers to the treatment being preferentially applied at and near the opening or openings of the feature than in the feature interior. For 3D NAND structures, the treatment may be conformal in the vertical direction such that the bottom wordline feature is treated to approximately the same extent as the top wordline feature, while non-conformal in that the interior of the wordline features are not exposed to the treatment or to a significantly lesser extent than the feature openings. A conformal treatment refers to the entire feature being treated to roughly the same extent. Such a treatment may be performed to mitigate line bending, for example, of features such as those in FIG. 2G.

The inhibition treatment treats the feature surface to inhibit subsequent metal nucleation at the treated surfaces. It can involve one or more of: deposition of an inhibition film, reaction of species with the Dep1 film to form a compound film (e.g., WN or Mo2N), and adsorption of inhibition species. During the subsequent deposition operation, there is a nucleation delay on the inhibited portions of the underlying film relative to the non-or lesser-inhibited portions (if any). According to various embodiments, the treatment may be a non-plasma operation or a plasma operation. If a non-plasma operation, it may be purely thermal or activated by some other energy such as UV. In some embodiments, the inhibition operation includes exposure to a metal precursor, which can be co-flowed with the inhibition gas or delivered in alternating pulses with it.

The plasma may be a remote or in-situ plasma. In some embodiments, it is generated from nitrogen (N₂) gas, though other nitrogen-containing gases may be used. In some embodiments, the plasma is a radical-based plasma, with no appreciable number of ions. Such plasmas are typically remotely generated. Nitrogen radicals may react with an underlying film to form a metal nitride in some embodiments. For thermal inhibition treatments, a nitrogen-and hydrogen-containing compound such as ammonia (NH₃) may be used. Hydrazine may also be used.

In some embodiments, the inhibition treatment further involves flowing a metal precursor. The metal precursor can be flowed with the nitrogen-containing gas or they can be flowed in alternating pulses. The metal precursor may be ramped up or down during the inhibition treatment. In some embodiments, the nitrogen-containing gas may be ramped up or down.

Returning to FIG. 5, at 520 the feature 502 is shown after an inhibition treatment. The inhibition treatment is a treatment that has the effect of inhibiting subsequent deposition on the treated surfaces 506. The inhibition may be characterized by an inhibition depth and an inhibition gradient. For non-conformal inhibitions, the inhibition varies with feature depth. For example, the inhibition may be greater at the feature opening than at the bottom of the feature and may extend only partway into the feature. In the depicted example of FIG. 5, the inhibition depth is about half of the full feature depth. In addition, the inhibition treatment may be stronger at the top of the feature, as graphically shown by the dotted line deeper within the feature. As indicated above, in other embodiments, the inhibition may be uniform throughout the feature.

Returning to FIG. 4, after operation 403, a second layer of metal is deposited in the feature in an operation 405. The second deposition may be referred to as Dep2 and may be performed by an ALD or CVD process. For deposition into 3D NAND structures, an ALD process may be used to allow for good step coverage throughout the structure. The Dep2 operation is influenced by the preceding inhibition operation. For example, if the feature openings are preferentially inhibited over the feature interior, deposition will preferentially occur in the feature interior. In another example, nitrogen on the surface of the deposited metal along the sidewalls of the feature may prevent metal-metal (e.g., tungsten-tungsten bonding) thereby reducing line bending.

In the example of FIG. 5, because deposition is inhibited near the feature opening, during the Dep2 stage shown at 530, the material preferentially deposits at the feature bottom while not depositing or depositing to a less extent at the feature opening. This can prevent the formation of voids and seams within the filled feature. As such, during Dep2, the material 504 may be filled in a manner characterized as bottom-up fill rather than the conformal Dep1 fill. As the deposition continues, the inhibition effect is removed. The incubation time, which is the time before the Dep2 film can grow on the treated surfaces is referred to as the Dep2 delay time.

In some embodiments, Dep2 includes a ramp process as show in FIG. 3A, with stage

1 being approximately the Dep2 delay time.

In the example of FIG. 5, as the Dep2 proceeds, the inhibition is overcome on all surfaces and the feature is completely filled with the material 504 as shown at 540. This operation may be stage 2 of a deposition process as shown in FIG. 3A.

While the DID process in FIG. 5 shows the feature preferentially inhibited at the top of the feature, in some embodiments, the entire feature may be inhibited. Such a process can be useful for preventing line bending, for example.

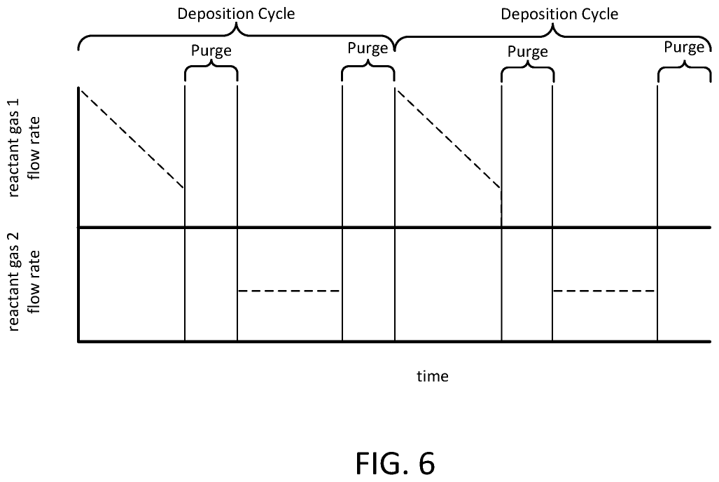

In the above description, ramping a flow rate is chiefly described in the context of a metal precursor during a CVD or inhibition operation in which the metal precursor is flowed continuously during the deposition or inhibition. A ramp process may also be employed in other contexts including ramping a metal precursor during an atomic layer deposition (ALD) sequence. FIG. 6 shows an example of two deposition cycles of an ALD process including a reactant 1 pulse/purge/reactant 2 pulse/purge sequence in each cycle. (The purge gas flow is not shown).

In the example, each pulse of the reactant 1 flow rate is ramped.

The techniques described herein may also be used in applications including dielectric film deposition including dielectric gap fill. For example, a dielectric precursor flow may be ramped down as fill reaches the top of the feature. In other embodiments, a flow may be ramped during other processes including flow of etch gases.

For filling features with metal, various metal precursors may be used. A metal precursor is a metal-containing compound that decomposes or reacts to form a metal film. Examples of tungsten precursors include tungsten hexafluoride (WF₆), tungsten pentachloride (WCI₅) and tungsten hexachloride (WCl₆), and tungsten hexacarbonyl (W(CO)₆). Metal-organic tungsten-containing precursor, such as MDNOW (methylcyclopentadienyl-dicarbonylnitrosyl-tungsten) and EDNOW (ethylcyclopentadienyl-dicarbonylnitrosyl-tungsten), may also be used.

To deposit molybdenum (Mo), Mo-containing precursors including molybdenum hexafluoride (MoF₆), molybdenum pentachloride (MoCl₅), molybdenum dichloride dioxide (MoO₂Cl₂), molybdenum tetrachloride oxide (MoOCl₄), and molybdenum hexacarbonyl (Mo(CO)₆) may be used.

To deposit ruthenium (Ru), Ru-precursors may be used. Examples of ruthenium precursors that may be used for oxidative reactions include (ethylbenzyl) (1-ethyl-1,4-cyclohexadienyl) Ru (0), (1-isopropyl-4-methylbenzyl) (1,3-cyclohexadienyl) Ru (0), 2,3-dimethyl-1,3-butadienyl) Ru (0) tricarbonyl, (1,3-cyclohexadienyl) Ru (0) tricarbonyl, and (cyclopentadienyl) (ethyl) Ru (II) dicarbonyl. Examples of ruthenium precursors that react with non-oxidizing reactants are bis (5-methyl-2,4-hexanediketonato) Ru (II) dicarbonyl and bis (ethylcyclopentadienyl) Ru (II).

To deposit cobalt (Co), cobalt-containing precursors including dicarbonyl cyclopentadienyl cobalt (I), cobalt carbonyl, various cobalt amidinate precursors, cobalt diazadienyl complexes, cobalt amidinate/guanidinate precursors, and combinations thereof may be used.

The metal-containing precursor may be reacted with a reducing agent as described above. In some embodiments, H₂ is used as a reducing agent for bulk layer deposition to deposit high purity films.

In some implementations, the methods described herein involve deposition of a nucleation layer prior to deposition of a bulk layer. Examples of reducing agents for nucleation layer deposition can include boron-containing reducing agents including diborane (B₂H₆) and other boranes, silicon-containing reducing agents including silane (SiHA) and other silanes, hydrazines, and germanes.

### EXPERIMENTAL

Features were filled with tungsten using a deposition-inhibition-deposition (DID) process. The DID process included deposition of a conformal film (Dep1), inhibition, and CVD deposition of a bulk film to fill the feature (Dep2). Three flow rate regimes for Dep2 were compared: Process 1-Dep2 flow rate of X sccm; Process 2-Dep2 flow rate of 3X sccm, no ramp; and Process 3-Dep2 flow rate of 3X sccm with ramp down. Fill quality was observed and stress at 1.2 kA measured for each feature.

| Process | Dep2 Flow Rate | Fill Quality | Stress |
|---|---|---|---|
| 1 | X | Poor | Y |
| 2 | 3X | Good | 1.6Y |
| 3 | 3X with ramp down | Good | 1.2Y |

The results show that ramp down can balance stress and fill performance.

### APPARATUS

Any suitable chamber may be used to implement the disclosed embodiments. Example deposition apparatuses include various systems, e.g., ALTUS® and ALTUS® Max, available from Lam Research Corp., of Fremont, California, or any of a variety of other commercially available processing systems.

In some embodiments, a first deposition may be performed at a first station that is one of two, five, or even more deposition stations positioned within a single deposition chamber. Thus, for example, diborane (B₂H₆) and tungsten hexachloride (WF₆) may be introduced in alternating pulses to the surface of the semiconductor substrate, at the first station, using an individual gas supply system that creates a localized atmosphere at the substrate surface. Another station may be used for inhibition treatment, and a third and/or fourth for subsequent bulk fill. In some embodiments, the inhibition may be performed in a separate module.

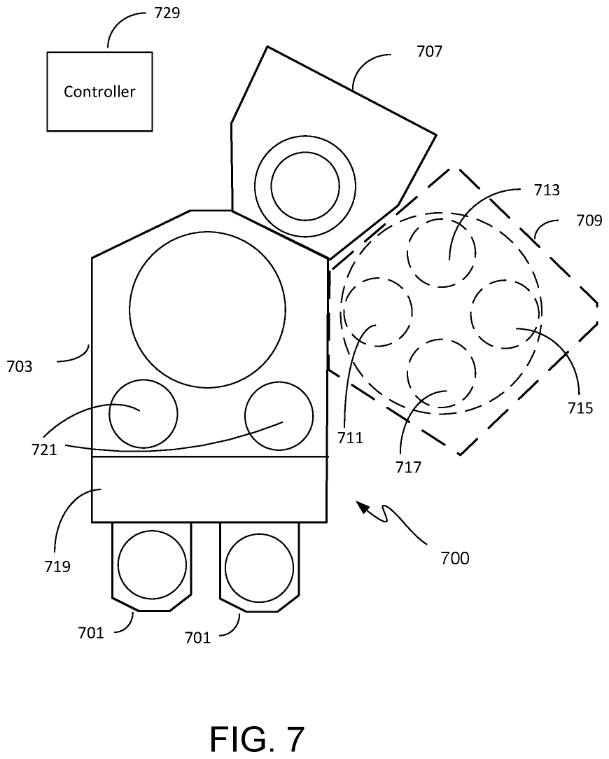

FIG. 7 is a schematic of a process system suitable for conducting deposition processes in accordance with embodiments. The system 700 includes a transfer module 703. The transfer module 703 provides a clean, pressurized environment to minimize risk of contamination of substrates being processed as they are moved between various reactor modules. Mounted on the transfer module 703 is a multi-station reactor 709 capable of performing ALD, CVD, and treatments such as inhibition according to various embodiments. Multi-station reactor 709 may include multiple stations 711, 713, 715, and 717 that may sequentially perform operations in accordance with disclosed embodiments. For example, multi-station reactor 709 may be configured such that station 711 performs a W, Mo, Co, or Ru nucleation layer deposition using a metal precursor and a boron-or silicon-containing reducing agent, station 713 performs ALD W, Mo, Co, or Ru bulk deposition of a conformal layer using H₂ as reducing agent, station 715 performs an inhibition treatment operation (with optional ramping), and station 717 may perform CVD bulk deposition with ramping of the metal precursor to fill the feature. Stations may include a heated pedestal or substrate support, one or more gas inlets or showerhead or dispersion plate.

In some embodiments, the multi-station module may be used for deposition (or other processes such as etch) with inhibition performed in a separate module such as module 707.

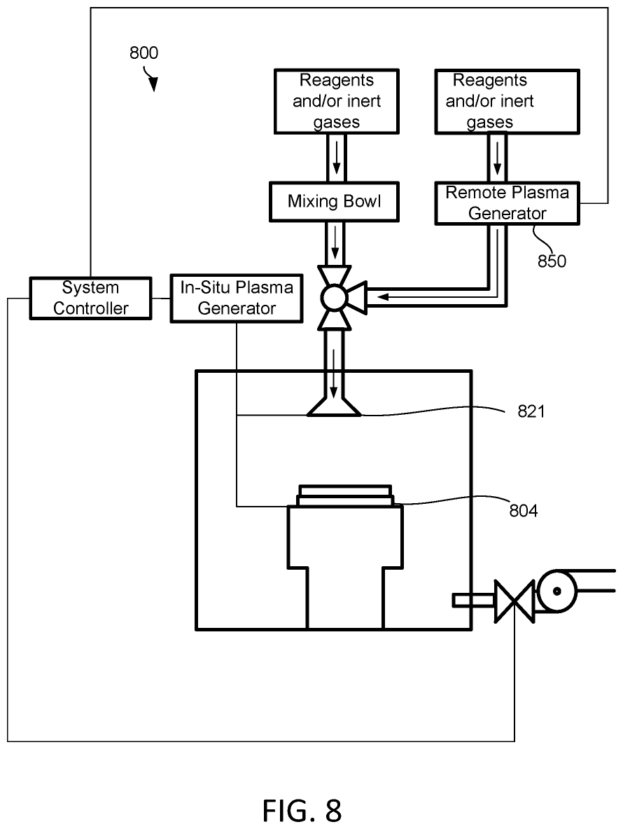

One example of a station is depicted in FIG. 8, which shows a station 800 configured for semiconductor processing. The station has a showerhead 821 and substrate support 804. The showerhead is connected to one or more gas sources as described above with reference to FIG. 1A. In some embodiments station may be connected to a remote plasma generator 850. In alternate embodiments, one or more of the showerhead and substrate support may be powered, with the station connected to a plasma generator for in situ plasma generation.

Returning to FIG. 7, also mounted on the transfer module 703 may be one or more single or multi-station modules 707 capable of performing plasma or chemical (non-plasma) pre-cleans, plasma or non-plasma inhibition operations, other deposition operations, or etch operations. The module may also be used for various treatments to, for example, prepare a substrate for a deposition process. The system 700 also includes one or more wafer source modules 701, where wafers are stored before and after processing. An atmospheric robot (not shown) in the atmospheric transfer chamber 719 may first remove wafers from the source modules 701 to loadlocks 721. A wafer transfer device (generally a robot arm unit) in the transfer module 703 moves the wafers from loadlocks 721 to and among the modules mounted on the transfer module 703.

In various embodiments, a system controller 729 is employed to control process conditions during deposition. The controller 729 will typically include one or more memory devices and one or more processors. A processor may include a CPU or computer, analog and/or digital input/output connections, stepper motor controller boards, etc.

The controller 729 may control all the activities of the deposition apparatus. The system controller 729 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 729 may be employed in some embodiments.

Typically, there will be a user interface associated with the controller 729. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 729. The signals for controlling the process are output on the analog and digital output connections of the deposition apparatus 700.

The system software may be designed or configured in many ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 729 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 729, depending on the processing requirements and/or the type of system, may be programmed to control any of the processes disclosed herein, including the delivery of processing gases, process gas flow ramp recipes, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 729, in some implementations, may be a part of or coupled to a computer that is integrated with, coupled to the system, otherwise networked to the system, or a combination thereof. For example, the controller 729 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 729 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, ramp recipes, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method comprising:
providing a substrate having a feature to be filled with a metal in a chamber; and
flowing a metal precursor and a reducing agent into the chamber to deposit metal in the feature in a chemical vapor deposition (CVD) operation, wherein the CVD operation comprises a ramp down stage in which the flow rate of the metal precursor into the chamber is ramped down from a first flow rate to a second flow rate.

2. The method of claim 1, wherein the CVD operation comprises a second stage, after the ramp down stage, in which the metal precursor flow rate is constant.

3. The method of claim 1, wherein the CVD operation comprises a second stage, prior to the ramp down stage, in which the metal precursor flow rate is constant.

4. The method of claim 1, wherein the reducing agent flow rate is constant during the ramp down stage.

5. The method of claim 1, wherein the reducing agent flow rate is ramped during the ramp down stage.

6. The method of claim 1, further comprising, prior to the CVD operation, performing an inhibition treatment to inhibit metal deposition.

7. The method of claim 6, wherein metal deposition is inhibited preferentially near the feature opening.

8. The method of claim 1, wherein the feature comprises a constriction and wherein a stage prior to the ramp down stage is used to fill a portion of the feature below the constriction.

9. The method of claim 8, wherein the ramp down stage is used to fill the constricted portion of the feature.

10. The method of claim 1, wherein the feature is a first feature having a first size and the substrate has a second feature having a second size, the second size being larger than the first size, and wherein the ramp down stage is used to complete fill of the first feature.

11. The method of claim 10, further comprising, after the first feature is completely filled, ramping up flow of the metal precursor from the second flow rate to a third flow rate.

12. A method comprising:
providing a substrate having a feature to be filled with a metal in a chamber; and
flowing a metal precursor and a reducing agent into the chamber to deposit metal in the feature in a chemical vapor deposition (CVD) operation, wherein the CVD operation comprises a ramp up stage in which the flow rate of the metal precursor into the chamber is ramped up from a first flow rate to a second flow rate.

13. The method of claim 12, wherein the substrate has a second feature, smaller than the feature and further includes filling the second feature, wherein the ramp up stage is performed after the second feature is completely filled and before the feature is completely filled.

14. The method of claim 12, wherein the CVD operation includes a second stage, after the ramp up stage, in which the metal precursor flow rate is constant.

15. The method of claim 12, wherein the reducing agent flow rate is constant during the ramp up stage.

16. The method of claim 12, wherein the reducing agent flow rate is ramped during the ramp up stage.

17. The method of claim 12, wherein the method further includes, prior to the CVD operation, performing an inhibition treatment to inhibit metal deposition.

18. An apparatus comprising:
a process chamber having a pedestal support and a showerhead;
one or more gas lines to direct gases to the showerhead; and
a controller having instructions configured to perform the method of claim 1.

19. An apparatus comprising:
a process chamber having a pedestal support and a showerhead;
one or more gas lines to direct gases to the showerhead; and
a controller having instructions configured to perform the method of claim 12.
